(19) United States
(12) Patent Application Publication
(10) Pub. No.: US 2020/0220952 A1
(43) Pub. Date: Jul. 9, 2020

(54) SYSTEM AND METHOD FOR ACCELERATING ISCSI COMMAND PROCESSING

(71) Applicant: ATTO Technology, Inc., Amherst, NY (US)

(72) Inventors: Barry J. Debbins, Lancaster, NY (US); Adam E. Chipalowsky, Williamsville, NY (US); David J. Cuddihy, Hamburg, NY (US)

(21) Appl. No.: 16/806,681

(22) Filed: Mar. 2, 2020

Related U.S. Application Data
(60) Provisional application No. 62/917,977, filed on Jan. 9, 2019.

(51) Int. Cl. H04L 29/06; H04L 29/08; G06F 30/331; H04L 12/801

(52) U.S. Cl. CPC H04L 69/163; H04L 67/1097; H04L 47/193; G06F 30/331; H04L 69/161

(57) ABSTRACT

A system and method for accelerating iSCSI storage traffic on a TCP/IP network over Ethernet. Ethernet storage frames are classified and deconstructed entirely in hardware by the use of a frame correlation engine, a TCP frame dissector and a number of protocol engines, providing iSCSI command processing without the involvement of a network protocol stack or TCP offload engine.

### FIELD OF THE INVENTION

The present invention relates generally to the field of networked data storage devices, and more particularly to a storage controller which implements Transmission Control Protocol and Internet Protocol (TCP/IP) and Internet Small Computer System Interface (iSCSI) storage protocols.

### BACKGROUND OF THE INVENTION

Computer storage networks implement various communications protocols to transmit and receive storage traffic. One example is a computer connected to an Ethernet networking system wherein a storage controller uses hardware to process the Physical and Link Layer protocols and a general purpose computer to handle the higher layer Network, Transport, Session and Application level protocols. In this example, TCP/IP are used at the Network, Transport and Session levels and the iSCSI protocol is used at the Application level. Taken collectively these protocols are referred to as a protocol stack, used to control the transfer of storage data between the data storage device and other network nodes.

Data storage traffic falls generally into three categories: data which is to be transferred from the network to a physical medium (Writes), data which is to be transferred from a physical medium to the network (Reads), and commands which are intended to modify the behavior or query the state of the storage device (Control).

High overhead in processing time through a network protocol stack often necessitates the use of hardware to offload the transport layer, known as a TCP offload engine, or TOE, while leaving some or all of the iSCSI processing to a general purpose processor. During normal write operation the TOE organizes all of the TCP/IP traffic for a single network connection into a data stream, strips any TCP/IP frame headers, then orders and aggregates all of the TCP/IP traffic into a series of data buffers in system memory. At this point the computer's Operating System (OS) is notified of the data, and a software processing thread is awakened to process the iSCSI headers, strip the iSCSI headers from the data, and transfer the remaining data buffers to physical storage medium.

In a system with a TOE and a general purpose processor, iSCSI read processing involves a general purpose processor directing a storage controller to retrieve the data from the physical storage medium into a series of data buffers in system memory. The general purpose processor then inserts iSCSI headers into the data stream as necessary for correct operation of the protocol. The aggregated iSCSI headers and data buffers are then passed from general purpose memory to the TOE to be broken into network level frames with network frame headers and transferred on the network.

U.S. Pat. No. 7,535,913 B2 (Minami et. al.) teaches a method of calculating iSCSI cyclic redundancy checks (CRCs) and splitting iSCSI Write protocol data units (PDUs) into header and data portions (Header Splitting). It also teaches a method of accepting iSCSI header and data segments from the protocol stack and preparing them for transmission on the network. In Minami et. al., the protocol stack is involved in the iSCSI processing, using a general purpose processor operating on data buffers in system memory. U.S. Pat. No. 7,389,462 B1 (Wang et al) similarly uses a very large instruction word VLIW proceesor with a layered software stack for iSCSI PDU translation and generation and subsequent data movement, and US Patent App. No. 2006/0262797A1 (Biran et al.) uses TOE for TCP, IP, and RDMA handling coupled to a processor running software for fast path packet validation and iSCSI protocol handling.

### BRIEF SUMMARY OF THE INVENTION

With parenthetical reference to corresponding parts, portions or steps or elements of the disclosed embodiment, merely for the purposes of illustration and not by way of limitation, the present invention provides a system and method within a storage controller for the simultaneous processing of TCP, IP and iSCSI protocols without a protocol stack or TOE, and without the direct intervention of a general purpose processor. In one embodiment, the invention comprises a hardware engine within a storage controller for accelerating iSCSI command processing, the hardware engine comprising a frame correlation engine for matching incoming TCP packets to connection descriptors; a TCP frame dissector configured to receive TCP packets from the frame correlation engine, for splitting TCP packets for delivery to an iSCSI command engine or SCSI command engine; an iSCSI command engine configured to receive frame data from the TCP frame dissector, for performing basic header segment validation; and a SCSI command engine configured to receive SCSI command information from the TCP frame dissector, for controlling flow of commands, data and/or status to a storage interface. In other aspects, the novel system comprises a copy engine configured to receive frame data from the TCP frame dissector, for copying storage data from the frame into data memory and/or a TCP composer, configured to build TCP packets, connected to a TCP dissector, for copying storage data from the frame into data memory. The novel system may be implemented through a field-programmable gate array (FPGA) such as an Intel® Arria 10, an application-specific integrated circuit (ASIC) or dedicated hardware. In certain aspects, the connection descriptors of novel system and method contain identification information and state information.

In one embodiment of the current invention, as used in a Write operation, a frame correlator (2) scans Ethernet and TCP/IP headers and compares them with entries in an initiator database (6), comprising an array of connection descriptors (14) which contain connection identification information and which also hold state information about the connection. Connection descriptors may contain a reference to a SCSI Descriptor (ACB) (12), which holds parameters specific to the processing of a SCSI command. Once a matching connection is found, the frame information, along with the connection descriptor index, is passed to a TCP dissector (5) in one aspect of this embodiment.

In another aspect, TCP dissector (5) may use the state held by the connection descriptor to determine whether the frame information can be handled by the mechanism. If the TCP dissector determines that the frame information is to be handled by the present invention, it may strip the frame headers, then split the data into pieces destined for one of the protocol engines: an iSCSI command engine (9), SCSI command engine (10) and copy engine (11).

In one embodiment, the iSCSI command engine (9) performs Basic Header Segment (BHS) validation. If the BHS describes the beginning of a new SCSI command the iSCSI command engine retrieves a SCSI descriptor (ACB) from a pre-allocated pool of descriptors, and a reference to the ACB may be stored in the connection descriptor (14) for use by the SCSI command engine (10) and copy engine (11). In another aspect, if the BHS describes the continuation of an outstanding command, the iSCSI command engine may find the associated ACB and update the ACB's state information to reflect the new BHS.

In yet another aspect, the SCSI command engine (10) determines if all of the data has been received. If not, the SCSI command engine (10) sends a request to the TCP composer to request the rest of the data. If all of the data has been received, the SCSI command engine (10) sends the ACB to the storage interface so it can be written to the disk. In another aspect, the copy engine (11) copies storage data from the frame into the data memory (7). Once all of the frames have been received and copied into the data memory (7), the storage interface (8) is notified that there is a complete SCSI Write command ready for transfer to the storage medium.

In certain aspects of the embodiment in FIG. 1, the TCP composer (15) needs to request the remaining data for the SCSI command. The TCP composer (15) may accomplish this by building an iSCSI ready-to-transfer (R2T) PDU packet and sending the packet to the NIC for transmission. In another aspect, the TCP composer reads the sense data from the ACB, builds a Response PDU packet and sends the packet to the NIC for transmission.

In certain embodiments of the invention, the protocol engines have the ability to determine that a command requires exception handling. Exceptions can be iSCSI commands with invalid parameters, SCSI commands which do not transfer bulk data, etc. If an exception is detected, the protocol engines have the ability to shunt frame information to an Off Ramp Queue (4).

One embodiment of the invention provides for handling the status and read data operations. In the exemplary system in FIG. 2, storage interface (201) stores a pointer to a SCSI Descriptor (ACB) (203) for each command. As data is read from the physical storage, the storage interface transfers the data from the physical storage to the data memory (202). In this embodiment, on command completion, status may be written to the SCSI Descriptor (ACB) associated with the storage command and the SCSI command engine (205) is notified of the command completion.

In other aspects, the SCSI command engine (205) translates the status returned by the storage interface into status conformant to SCSI standards and notifies the iSCSI command engine (206); and the iSCSI command engine writes the proper header information into the ACB (203) and updates the connection descriptor's (207) state. The iSCSI command engine (206) may then update the connection descriptor with the iSCSI header for the command response along with a reference to any response data residing in the data memory (202), then notify the TCP composer (214) of the response to be transmitted. In one emboduiment, TCP composer (214) uses the information in the command descriptor to transmit the response and data to the host via the Host interface 211 (NIC).

In another aspect, the TCP dissector (209) contains TCP ACK handling logic as part of its receive functionality in order to recognize and process TCP acknowledgement numbers and, when transmitted data has been acknowledged, the TCP dissector clears ACB and connection descriptor references to the data memory and frees ACBs for reuse.

In another aspect of the invention, the SCSI command engine (205) may detect SCSI command errors that require additional handling via a general purpose processor.

### BRIEF DESCRIPTION OF THE DRAWINGS

FIG. 1 illustrates the components in one embodiment of the system as used for a write operation, along with data flow from the network interface to the storage interface.

FIG. 2 illustrates the components in one embodiment of the system as used for a read or status operation, along with data flow from the storage interface to the network interface.

FIG. 3 illustrates the logic flow of the frame correlator in one embodiment of the invention.

FIG. 4 illustrates the logic flow of the TCP dissector in one embodiment of the invention.

FIG. 5 illustrates the logic flow of the iSCSI command engine in one embodiment of the invention.

FIG. 6 illustrates the logic flow of the SCSI command engine in one embodiment of the invention.

FIG. 7 illustrates the logic flow of the TCP composer in one embodiment of the invention.

FIG. 8 is a diagram of the connection descriptor in one embodiment of the invention.

FIG. 9 is a diagram of the states of a connection in one embodiment of the invention.

FIG. 10 is a representative SCSI Descriptor (ACB) in one embodiment of the invention.

### DETAILED DESCRIPTION OF THE PREFERRED EMBODIMENTS

At the outset, it should be clearly understood that like reference numerals are intended to identify the same structural elements, portions or surfaces consistently throughout the several drawing figures, as such elements, portions or surfaces may be further described or explained by the entire written specification, of which this detailed description is an integral part. Unless otherwise indicated, the drawings are intended to be read together with the specification, and are to be considered a portion of the entire written description of this invention. The following description is presented to enable any person skilled in the art to make and use the inventions claimed herein. Various modifications to the disclosed embodiments will be readily apparent to those skilled in the art.

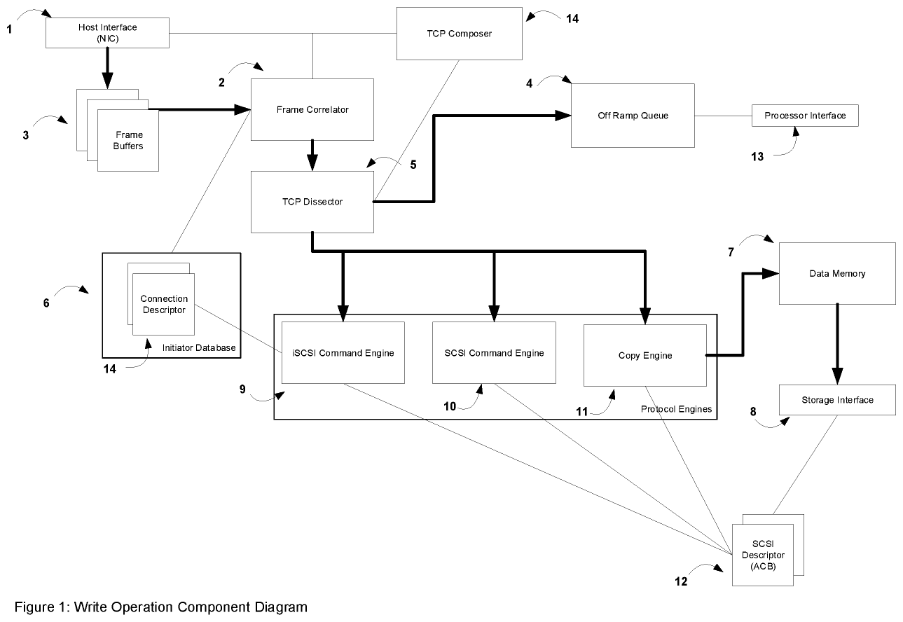

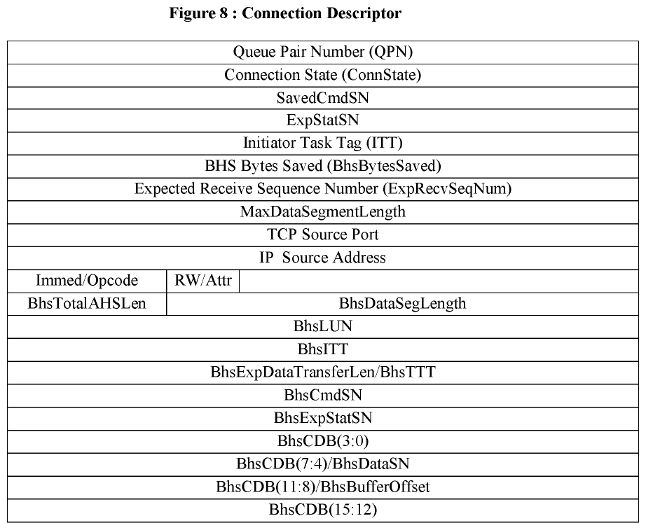

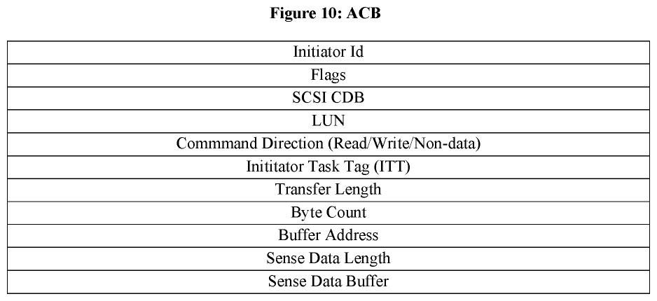

Referring now to the drawings, and more particularly to the exemplary system in FIG. 1 thereof, the narrow lines indicate the transfer of control information whereas the thick arrows show the flow of storage data through the mechanism. The host interface 1 accepts Ethernet frames and transfers them, with headers intact, to the incoming frame buffers 3. The frame correlator 2 scans the Ethernet and TCP/IP headers and compares them with entries in the initiator database 6. The initiator database is composed of an array of connection descriptors 14 which contain connection identification information such as Ethernet source and destination addresses, IP source and destination addresses and TCP source and destination port numbers, as described in the example connection descriptor in FIG. 8. The connection descriptor may store more or less information than that described in FIG. 8, however, or have the information represented in a different order. Persons of ordinary skill in the art will recognize that cerain configurations of the command descriptor will favor execution speed over space, and others will favor space optimization. For example, if the NIC did not segregate flows based on queue pairs and ports, the first two fields in FIG. 8 could be a hardware assigned connection ID. Also, the ordering of the fields in the connection descriptor of FIG. 8 are arbitrary. The BHS could be held in a separate cache with the connection descriptor containing a reference to the cache entry. Or, the fields in the BHS cache could be rearranged if a hardware designer found it useful, for example. A connection descriptor also holds state information about the connection, including TCP sequence numbers, iSCSI sequence numbers and expected data length and offset for the current SCSI command. The connection descriptor may contain a reference to a SCSI Descriptor (ACB) 12, which holds parameters specific to the processing of a SCSI command, as shown in the example in FIG. 10. The ACB may store more or less information than that described in FIG. 10, however, or have the information represented in a different order. For example, in another embodiment, command direction is determined from the SCSI CDB instead of being held in a separate field, and in another embodiemnt, sense data is stored outside of the ACB in a data buffer pointed to by buffer address instead of being buffered in the ACB directly. In a preferred embodiment, the frame correlator uses a multibit comparator to simultaneously compare physical port number and queue pair number (QPN) of each connection descriptor with the physical port number and QPN of the received frame. Once a matching connection is found, the frame information, along with the connection descriptor index, is passed to the TCP dissector 5.

The TCP dissector 5 uses the state held by the connection descriptor to determine whether the frame information can be handled by the protocol engines 9, 10, 11. If it cannot be handled, the frame with header and data are funneled to the off ramp queue 4, which signals the processor interface 13 that an exception in processing has occurred. If the processor needs to be involved in the handling of this frame the headers and data are funneled to the off ramp queue 4, which signals the processor interface 13 that an exception in processing has occurred. The off ramp queue 4 generally handles (and the protocol engines of the preferred embodiment, therefore, do not handle) iSCSI PDUs that do not contain valid SCSI commands. PDU opcodes such as Login, Logout, Text Messages and iSCSI NOP are not SCSI commands. Since one aspect of the novel system and method is concerned with the high speed transfer of storage data, the off ramp queue 4 may also handle SCSI commands that do not contain large volumes of storage data such as SCSI inquiry, read capacity, mode sense and mode select, reserve and release commands, read and write buffer commands, etc.

Once the TCP dissector 5 has determined that the frame information is to be handled by the protocol engines, it strips the frame headers, then splits the data into pieces destined for one of the protocol engines 9, 10, 11. Frame data containing the iSCSI Basic Header Segment (BHS) is cached in the command descriptor and passed to the iSCSI Command Engine 9. A reference to storage data is passed to the copy engine 11. All protocol engines 9,10,11 also have access to the current connection descriptor.

The iSCSI command engine 9 performs BHS validation. If the BHS describes the beginning of a new SCSI command the iSCSI command engine 9 retrieves a SCSI descriptor (ACB) 12 from a pre-allocated pool of descriptors. A reference to the ACB is stored in the connection descriptor 14 for use by the SCSI command engine 10 and copy engine 11.

If the BHS describes the continuation of an outstanding command the iSCSI command engine 9 finds the associated ACB 12 and updates the ACB's state information to reflect the new BHS.

The SCSI command engine 10 directs the flow of the ACB 12 through the SCSI command processing. When handling a SCSI Write command, the SCSI command engine 10 uses information stored in the ACB 12 to determine if all of the data has been received for the command. If not, the SCSI command engine 10 sends the ACB 12 to the TCP composer to request the remaining data. If the ACB 12 indicates that the data has been written to the storage device, the SCSI command engine 10 translates the status returned by the storage interface 8 into status conformant to SCSI standards and notifies the iSCSI command engine 9 of the completion. The iSCSI command engine 9 writes the proper iSCSI header information into the ACB 12, references the connection descriptor 14 in the ACB 12 and updates the connection descriptor's 14 state.

The copy engine 11 copies storage data from the frame into the data memory 7 using buffer location, offset and length information in the ACB. Once all of the frames have been received and copied into the data memory 7 the storage interface 8 is notified that there is a complete SCSI Write command ready for transfer to the storage medium. By copying the data, the copy engine 11 frees up frame buffers for reuse and coalesces all the data into a single block of data memory, making the transfer to the storage interface more efficient.

When more data is required for a SCSI Write command, the TCP composer 15 uses the information in the command descriptor and the ACB 12 to build a R2T PDU to send to the host via the Host interface 1 (NIC). At the completion of the SCSI Write command, the TCP composer 15 uses the information in the command descriptor to transmit the response to the host via the Host interface 1 (NIC).

In another aspect of the invention each of the protocol engines have the ability to determine that a command requires exception handling. Exceptions can be iSCSI commands with invalid parameters, SCSI commands which do not transfer bulk data, etc. If an exception is detected each protocol engine has the ability to shunt frame information to the off ramp queue 4 in order to have the processor handle the exception.

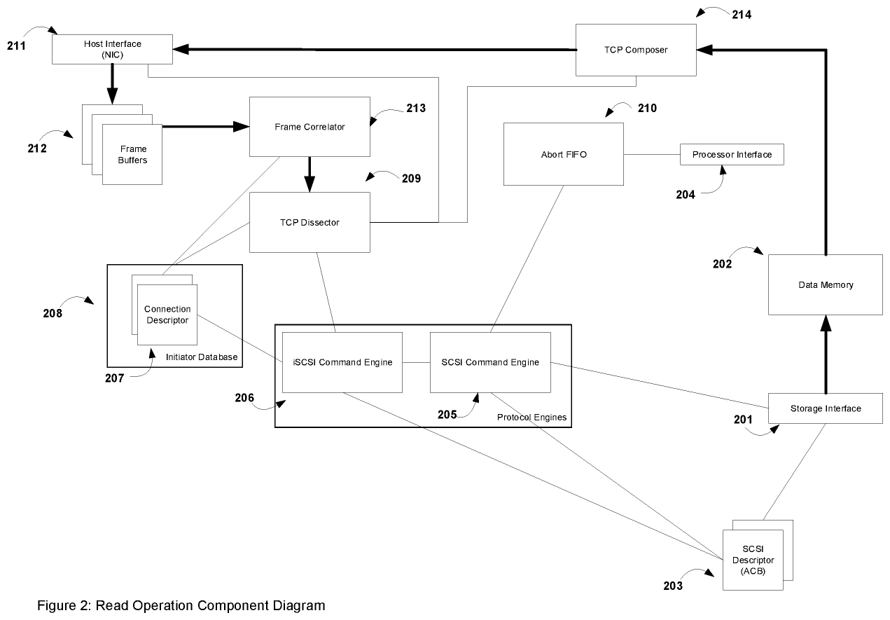

FIG. 2 shows an exemplary system which handles status and read data operations. In FIG. 2, the narrow lines indicate the transfer of control information whereas the thick arrows show the flow of storage data through the mechanism. The storage interface 201 stores a pointer to a SCSI Descriptor (ACB) 203 for each command. As data is read from the physical storage, the storage interface 201 transfers the data from the physical storage to the data memory 202. On command completion, status is written to the SCSI Descriptor (ACB) 203 associated with the storage command. The SCSI command engine 205 is notified of the command completion.

In a preferred embodiment, the SCSI command engine 205 translates the status returned by the storage interface 201 into status conformant to SCSI standards and notifies the iSCSI command engine 206 of the completion. The iSCSI command engine 206 updates the connection descriptor 207 with the iSCSI header for the command response along with a reference to any response data residing in the data memory 202, then notifies the TCP composer 214 of the response to be transmitted.

The TCP composer 214 uses the information in the command descriptor to transmit the response and data to the host via the Host interface 211 (NIC). This may entail the splitting of response data into individual Ethernet frames, each with its own header, or may make use of the large transmit offload capability available in many NICs.

Since TCP is a reliable protocol, depending on acknowledgment from the receiving side, the data memory 202 and response-specific connection information cannot be freed for reuse until the response and data have been acknowledged. The TCP dissector 209 may contain TCP ACK handling logic as part of its receive functionality in order to recognize and process TCP acknowledgement numbers. When transmitted data has been acknowledged, the TCP dissector 209 clears ACB 203 and connection descriptor 207 references to the data memory 202 and frees ACBs 203 for reuse.

In another aspect of the preferred embodiment, the TCP dissector 209 has TCP retransmit signalling consisting of a timer and TCP ACK logic in order to signal the TCP composer when a retransmit is necessary. The TCP composer 214 contains logic to retransmit iSCSI headers and data via the NIC 211 according to the requirements of the TCP protocol.

An additional capability of the TCP composer 214 is provided in a preferred embodiment: the generation of TCP ACK numbers and zero-length ACK frames for transmission via the NIC 211. TCP ACK numbers are stored in the connection descriptor 207 for inclusion in TCP transmissions in accordance with the TCP protocol.

In another aspect of the preferred embodiment, the SCSI command engine 205 detects SCSI command errors that require additional handling via a general purpose processor. In that situation, the SCSI command engine 205 places a reference to the ACB 203 requiring extra processing into the storage interface 210 for handling by the general purpose processor.

Additionally, each component which interacts with ACBs 203 may have the capability of detecting ACBs 203 that have been aborted by SCSI task management functions. The reference to an ACB 203 for each aborted SCSI command is passed to the storage interface 210 for handling by the general purpose processor.

In certain preferred embodiments, the novel hardware engine is capable of maintaining and/or configured to maintain at least 64 simultaneous TCP connections. In certain preferred embodiments, the storage interface is capable of maintaining and/or configured to maintain connections to 1024 or more storage devices.

### Detailed Logic Flow—Frame Corrlator

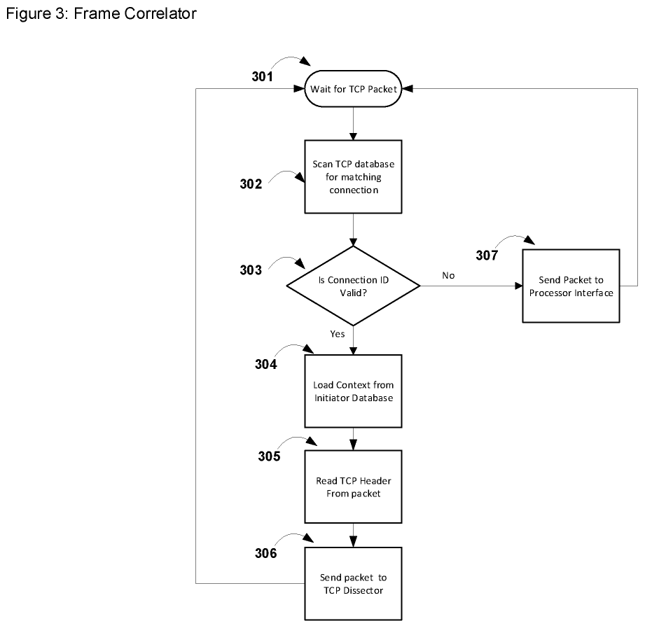

The frame correlator in FIG. 3 is responsible for matching a received TCP packet to an internal connection ID. When a TCP packet is received 301 the Inititaor database is scanned 302 based on the packet's queue pair number (QPN) and physical port number. A connection ID is generated by the scanner. If the connection ID is valid 303 the context is loaded from the initiator database 304, the TCP header is read from the packet frame buffer and sent to the TCP dissector 306. If the connection ID generated is not valid the packet is sent 307 to the processor interface 13,204 for handling by the general purpose processor.

### Detailed Logic Flow—TCP Dissector

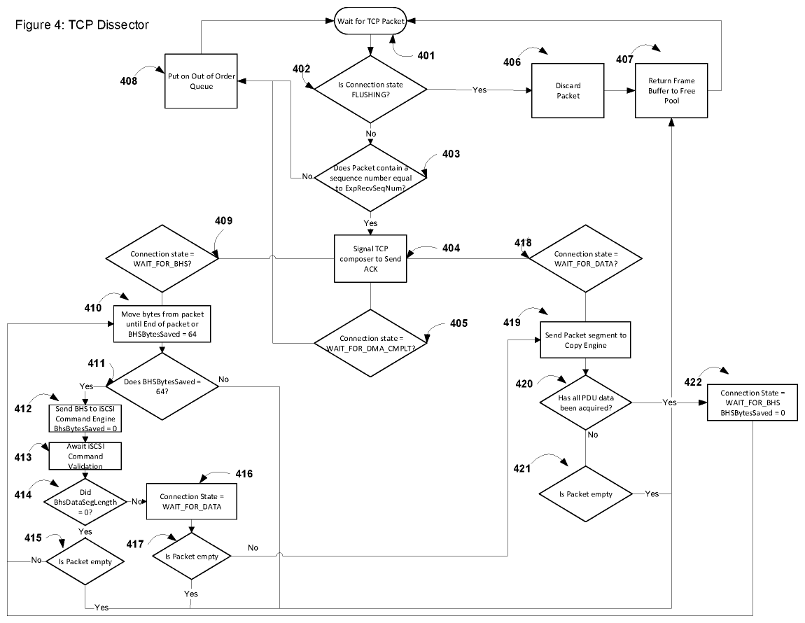

The TCP dissector in FIG. 4 splits incoming TCP packets into pieces to be handled by the various protocol engines. Once a TCP packet is received, if the connection state is FLUSHING 402 the packet is discarded 406 and the frame buffer is returned to the free pool 407. If not in FLUSHING state the packet sequence number is checked against the sequence number stored in the connection descriptor 403. If the sequence number indicates an out of order TCP packet the packet is placed on the connection's out of order queue 408 and the TCP dissector waits to process the next packet 401.

If the TCP dissector detected a valid, in-order TCP packet the TCP composer is signaled to generate a TCP acknowledgment 404 and the TCP dissector takes further action based on connection state 405,409,418.

For a connection in WAIT_FOR_DMA_CMPLT state 405, the packet is moved to the connection's out of order queue for further processing 408.

For a connection in WAIT_FOR_BHS state 409 the TCP dissector transfers the number of bytes remaining in the current BHS into the connection descriptor BHS cache. If the bytes left in the packet does not complete the BHS 411 the frame buffer is returned to the free pool 407 and the TCP dissector waits to process the next packet. If an entire BHS has been received, the TCP dissector pauses to wait for the iSCSI command engine to validate the BHS 413. Validation in the iSCSI command engine occurs simultaneous to TCP dissector processing due to the engines' concurrent access to the BHS cache in the connection descriptor. Once validated if there are bytes remaining in this iSCSI PDU 414 the connection state is set to WAIT_FOR_DATA 416 and the packet is sent to the copy engine 417. Since there may be more than one BHS in a single TCP packet the packet is checked for additional BHS data 415 and a new BHS is generated, if necessary 410.

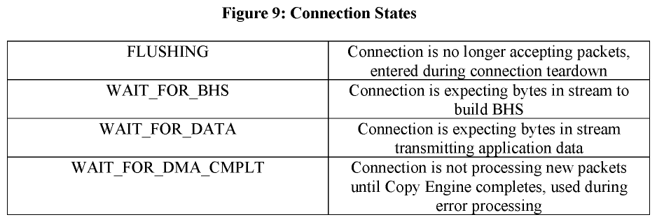

For a connection in WAIT_FOR_DATA state 418 the packet segment is sent to the copy engine based on the remaining count in the current BHS 419. If all PDU data has been acquired the connection state is reset to WAIT_FOR_BHS 422. Any remaining data in the TCP packet is scanned for the new BHS 410. Multiple iterations of BHS and/or data handling are handled by the TCP dissector. Each of the foregoing connection states is also described in FIG. 9.

### Detailed Logic Flow—iSCSI Command Engine

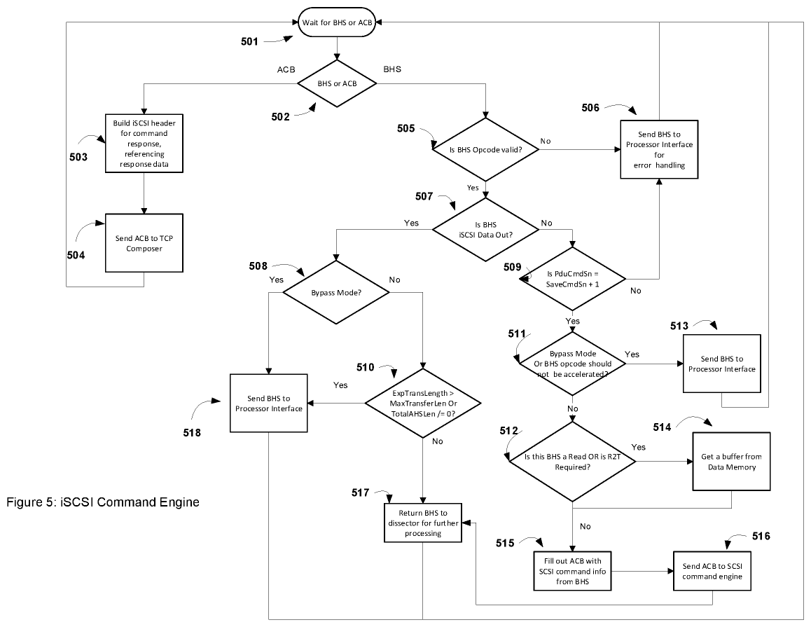

The iSCSI command engine in FIG. 5 handles iSCSI status and/or data to be returned from the connected storage to the host as well as new commands from the host to the storage. Status and/or data to be returned will be sent to the iSCSI command engine as an ACB whereas new commands will be formatted as a BHS.

The iSCSI command engine waits for a BHS or ACB 501. If an ACB is received 502 the iSCSI command engine creates an iSCSI header for the command response 503 and sends the ACB to the TCP composer 504.

If a new iSCSI BHS is received the opcode is validated 505. Invalid opcodes are sent to the processor interface 13,204 for error handling 506. Valid opcodes are checked for iSCSI data out opcode, which requires special handling 507. If the connection is in BYPASS state 508 the data out BHS is sent to the processor interface 13,204. If bypass mode is not enabled the BHS expected transfer length and AHS lengths are validated 510. A data out which fails these is sent 518 to the processor interface 13. If the validation passes the iSCSI command engine returns the packet to the TCP dissector 5 for further processing 517.

A BHS that is not an iSCSI data out has the PDU command sequence number validated 509. A BHS that fails sequence number validation is sent to the processor interface 204 for error handling 506. If the connection state is BYPASS or the BHS opcode is not meant to be accelerated 511 the BHS will be sent 513 to the processor interface 204.

iSCSI commands may require a handshake between the host and the target, called a ready-to-transfer PDU (R2T). If additional data buffering is required for read or write 512 the iSCSI command engine acquires a buffer from data memory 514. SCSI command information is then transferred to the ACB 515 and the ACB is sent to the SCSI command engine 516. The packet is then returned to the TCP dissector for further processing 517.

### Detailed Logic Flow—SCSI Command Engine

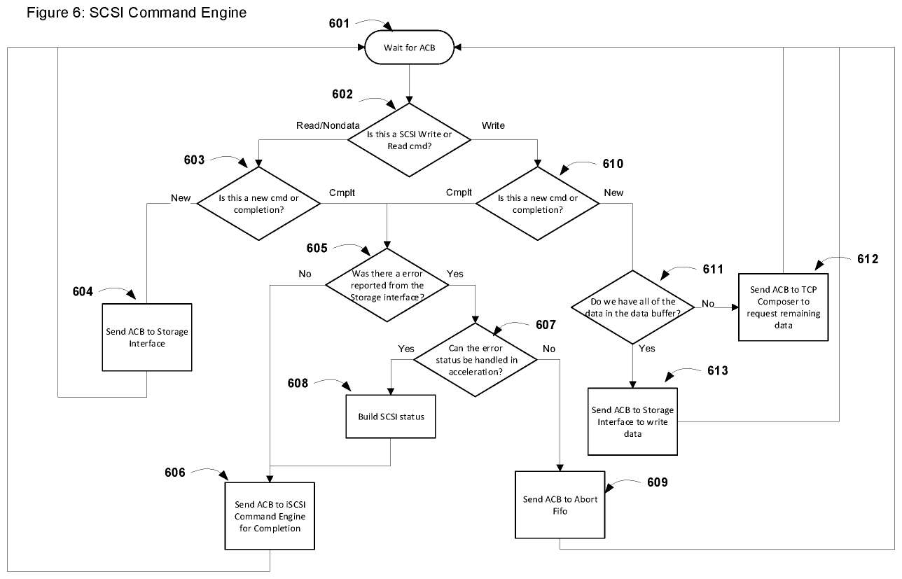

The SCSI command engine illustrated in FIG. 6 controls the flow of commands, data and status to the storage interface. The SCSI command engine waits for an ACB to process 601. Write commands (data out from the initiator) contain an iSCSI data phase prior to starting the command on the SCSI interface, so processing in the SCSI command engine is split into read/nondata and write processing. The ACB's command direction is checked 602. Reads are checked whether the command is new (generated by the iSCSI engine) or a completion (from the storage interface) 603. New commands are sent 604 to the storage interface 201. Write commands are likewise checked for new or completion 610. If the write command is new the ACB is checked to see if all of the data has been received by the TCP dissector 611. If there is data required the SCSI command sends the ACB to the TCP composer 612. The TCP composer will create an R2T to send to host to request the remaining data. If all data has been received the ACB is sent 613 to the storage interface 8.

Command completions from the storage interface are checked for error status 605. If no error the ACB is forwarded to the iSCSI command engine for completion 606. If an error did occur and the error can be handled by the acceleration a SCSI status is written to the ACB 608 and the ACB is forwarded to the iSCSI command engine for completion 606. Complex errors which are not handled by the SCSI command engine are sent 609 to the storage interface 210.

### Detailed Logic Flow—TCP Composer

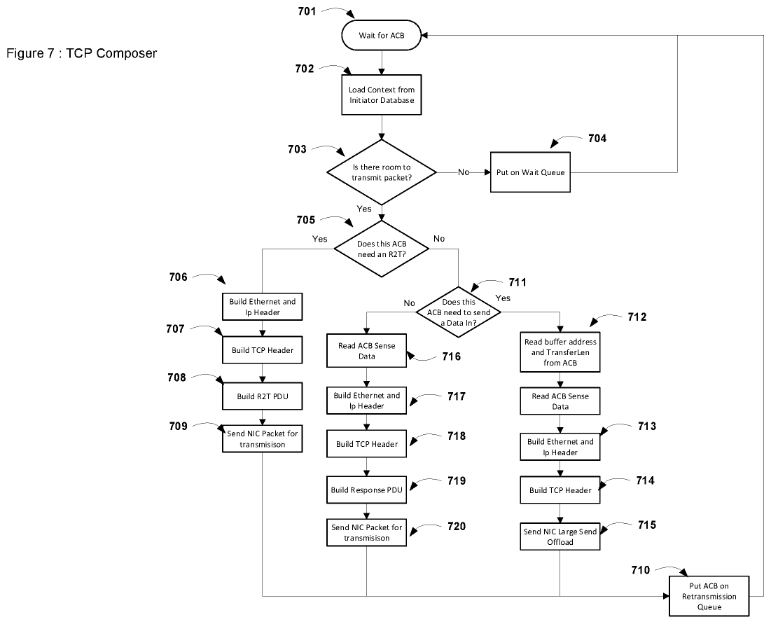

The TCP Composer illustrated in FIG. 7 generates Ethernet, TCP and IP headers for network packets to be transmitted. When an ACB is received by the TCP composer 701 the connection descriptor is read from the initiator database 702. The NIC 1,211 is scanned to determine if there is room in its output queue 703. If there is no room the ACB is placed on the TCP composer's wait queue 704.

If a Ready to Transfer iSCSI message (R2T) is required for this ACB 705 the required headers are built 706, 707. The R2T PDU is created 708 and the TCP packet is enqueued to the NIC 709. The ACB is then placed on the retransmission queue 710.

If a R2T is not required 705 the ACB is checked to see if an iSCSI data in PDU is required 711 along with status. If a data in PDU is required the buffer address and transfer length from the ACB are used to configure the data transfer 712. The sense data, if any, is read from the sense data buffer in the ACB. The required headers are built 713,714 and the transfer is enqueued to the NIC as a large send offload 715. The ACB is then placed on the retransmission queue 710.

If a R2T is not required 705 and the ACB does not need a data in response sent 711 the sense data is read from the sense data buffer in the ACB 716. The required headers are built 717,718 and the iSCSI status PDU is created using the sense data from the ACB 719. The TCP packet is enqueued to the NIC 720 and the ACB is placed on the retransmission queue 710.

In a preferred embodiment, the novel system and method is implemented in a field-programmable gate array (FPGA) such as an Intel® Arria 10. The FPGA is connected to a NIC via the PCIe bus and communicates using methods defined by the NIC vendor. However, the system and method may be implemented in an ASIC or custom logic.

The present invention contemplates that many changes and modifications may be made. Therefore, while an embodiment of the improved system and method has been shown and described, and a number of alternatives discussed, persons skilled in this art will readily appreciate that various additional changes and modifications may be made without departing from the spirit of the invention, as defined and differentiated by the following claims.

What is claimed is:

1. A hardware engine, within a storage controller, for accelerating iSCSI command processing on a TCP/IP network without a protocol stack or TCP offload engine, comprising:
a frame correlation engine for matching an incoming TCP packet to a connection descriptor;
a TCP frame dissector configured to receive one or more TCP packets from the frame correlation engine, for splitting TCP packets for delivery to an iSCSI command engine or SCSI command engine;
an iSCSI command engine configured to receive frame data from the TCP frame dissector, for performing basic header segment validation; and
a SCSI command engine configured to receive SCSI command information from the TCP frame dissector, for controlling flow of one or more commands, data or status to a storage interface.

2. The hardware engine of claim 1, implemented in a field-programmable gate array.

3. The hardware engine of claim 1, implemented in an application-specific integrated circuit.

4. The hardware engine of claim 1, further comprising a copy engine configured to receive frame data from the TCP frame dissector, for copying storage data from the frame into data memory.

5. The hardware engine of claim 4 wherein said iSCSI command engine, said SCSI command engine and said copy engine work concurrently on the same TCP packet.

6. The hardware engine of claim 1, further comprising a TCP composer, configured to build TCP packets, connected to said TCP dissector, which uses said command descriptors to build an iSCSI R2T PDU for requesting additional data in a Write operation.

7. The hardware engine of claim 1 wherein said iSCSI commands are processed without a protocol stack.

8. The hardware engine of claim 1 wherein said iSCSI commands are processed without a TCP offload engine.

9. The hardware engine of claim 1 wherein said iSCSI command engine and said SCSI command engine work concurrently on the same TCP packet.

10. The hardware engine of claim 1 wherein said connection descriptors contain connection identification information and state information.

11. The hardware engine of claim 1, further comprising a plurality of TCP connections, wherein said hardware engine is configured to maintain 64 simultaneous TCP connections.

12. The hardware engine of claim 1, wherein the hardware engine is connected to a plurality of network ports.

13. The hardware engine of claim 1, wherein said storage interface maintains connections to 1024 or more storage devices.

14. The hardware engine of claim 1, further comprising an off ramp queue for handling exceptions in processing determined by said TCP frame dissector.

15. A hardware engine, within a storage controller, for accelerating iSCSI command processing on a TCP/IP network without a protocol stack or TCP offload engine, comprising:
a frame correlation engine for matching an incoming TCP packet to a connection descriptor, said command descriptor comprising state information;
a TCP frame dissector configured to receive one or more TCP packets from the frame correlation engine, for splitting TCP packets for delivery to two or more protocol engines selected from a group comprising: (a) an iSCSI command engine for performing basic header segment validation, (b) a SCSI command engine for controlling flow of one or more commands, data or status to a storage interface, and (c) a copy engine for copying storage data from the frame into data memory;
wherein said TCP frame dissector uses the state information held by the connection descriptor to determine whether the frame information can be handled by one or more of said protocol engines; and
wherein said hardware engine is implemented in a FGPA or an ASIC.

16. The hardware engine of claim 15, further comprising an off ramp queue for handling exceptions in processing determined by said TCP frame dissector.

17. The hardware engine of claim 15 wherein said iSCSI command engine, said SCSI command engine and said copy engine are configured to work concurrently on the same TCP packet.

18. The hardware engine of claim 15 wherein said iSCSI commands are processed without a protocol stack.

19. The hardware engine of claim 15 wherein said iSCSI commands are processed without a TCP offload engine.

20. The hardware engine of claim 15, further comprising a TCP composer, configured to build TCP packets, connected to said TCP dissector, which uses said command descriptors to build an iSCSI R2T PDU for requesting additional data in a Write operation.
